(19) United States
(12) Patent Application Publication
(10) Pub. No.: US 2025/0107072 A1
(43) Pub. Date: Mar. 27, 2025

(54) MEMORY DEVICE WITH TWISTED BIT LINES AND METHODS OF MANUFACTURING THE SAME

(71) Applicant: Taiwan Semiconductor Manufacturing Company, Ltd., Hsinchu (TW)

(72) Inventors: Ji-Kuan Lee, Hsinchu (TW); Chieh Lee, Hsinchu (TW); Chia-En Huang, Hsinchu (TW); Yao-Jen Yang, Hsinchu (TW)

(73) Assignee: Taiwan Semiconductor Manufacturing Company, Ltd., Hsinchu (TW)

(21) Appl. No.: 18/472,862

(22) Filed: Sep. 22, 2023

(51) Int. Cl. H10B 12/00

(52) U.S. Cl. CPC H10B 12/485; H10B 12/03; H10B 12/05; H10B 12/482

(57) ABSTRACT

A memory device includes a substrate; a plurality of metallization layers disposed over the substrate; a plurality of memory cells, each of the plurality of memory cells including a transistor and a capacitor; and a bit line coupled to a corresponding set of the plurality of memory cells. The bit line comprises at least a first conductor structure and a second conductor structure that extend along a first lateral direction and are disposed in a first one of the plurality of metallization layers. The first conductor structure and the second conductor structure are physically spaced from each other, but are electrically coupled to each other through conductor structures disposed in one or more of the plurality of metallization layers.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory device including a number of BEOL memory cells, in accordance with some embodiments.

FIG. 2 illustrates a circuit diagram of one the BEOL memory cells of the memory device of FIG. 1, in accordance with some embodiments.

FIG. 3 illustrates a perspective view of the BEOL memory cell of FIG. 2, in accordance with some embodiments.

FIG. 4 illustrates a perspective view of a memory array including a number of the BEOL memory cells of FIG. 2, in accordance with some embodiments.

FIG. 5 illustrates a cross-sectional view of a memory device including a number of the BEOL memory cells of FIG. 2, in accordance with some embodiments.

FIGS. 6-14 illustrate various example layouts of a number of twisted bit lines of a memory device, respectively, in accordance with some embodiments.

FIG. 15 illustrates a schematic diagram of twisted bit lines, in accordance with some embodiments.

FIG. 16 illustrates an example layout corresponding to the schematic diagram of FIG. 15, in accordance with some embodiments.

FIG. 17 illustrates a schematic diagram of twisted bit lines, in accordance with some embodiments.

FIG. 18 illustrates an example layout corresponding to the schematic diagram of FIG. 17, in accordance with some embodiments.

FIG. 19 illustrates a schematic diagram of twisted bit lines, in accordance with some embodiments.

FIG. 20 illustrates an example layout corresponding to the schematic diagram of FIG. 19, in accordance with some embodiments.

FIG. 21 illustrates a flow chart of an example method for fabricating a memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Many electronic products need various amounts of memory devices (e.g., memory bit cells or memory cells) to store information, e.g., data. One common configuration of the memory bit cells consist of an access transistor and a capacitor electrically connected in series, which is sometimes referred to as a one-transistor-one-capacitor (1T1C) cell. Data can be either stored in the memory cells during a write mode, or data may be retrieved from the memory cells during a read mode. Source/drain terminals of the access transistors of the memory cells are connected to internal signal lines, sometimes referred to as bit or digit lines. Gate terminals of the access transistors of the memory cells are connected to addressing lines, sometimes referred to as word lines. The word line selects an access transistor to be turned on, and the bit line is thus coupled to a corresponding capacitor via an induced (e.g., turned on) channel of the access transistor.

A thin-film transistor (TFT) is a kind of field-effect transistor including a channel layer, a gate terminal, and source and drain terminals, over a supporting but non-conducting substrate. A TFT differs from a conventional transistor, where a channel of the conventional transistor is typically formed within, from, or based on a substrate, such as a silicon substrate. TFTs have emerged as an attractive option to fuel Moore's law by integrating TFTs in the back-end-of-line (BEOL) network, while leaving the silicon substrate areas for high-speed transistors. A TFT may be used as the access transistor for a memory cell. A memory device including such memory cells is sometimes referred to as a BEOL memory device. However, current designs and implementations of BEOL memory devices still face many challenges. For example, the bit lines of a BEOL memory device are typically arranged as parallel conductor lines in a single metallization layer. With this configuration, noise coupled to one of the bit lines is easily coupled to other bit lines, which may disadvantageously degrade performance of the BEOL memory device.

The present disclosure provides various embodiments of a BEOL memory device including a plural number of memory cells, each of which consists of a transistor and a capacitor. The BEOL memory device may further include a number of bit lines, each of which is operatively coupled to a corresponding set of the memory cells. In various embodiments of the present disclosure, these bit lines may be “twisted” based on each bit line including a plural number of different portions physically spaced from one another. The term “twisted bit lines,” as disclosed herein, may refer to a number of bit lines respectively having some portions overlapped with each other, when viewed from the top. For example, a first bit line may include at least a first end portion and a second end portion, which are implemented as a first conductor line and a second conductor line of a first one of BEOL metallization layers, respectively; and a second bit line may include at least a third end portion and a fourth end portion, which are implemented as a third conductor line and a fourth conductor line of the first BEOL metallization layer, respectively. Further, each of the first and second bit lines can include one or more other different portions coupled between their respective end portions, which may be disposed across one or more other BEOL metallization layers. By configuring the bit lines in this way, even if noise is present and coupled to a certain bit line, the noise may be spread out through different portions of the bit line, which may further reduce coupling across different bit lines. As such, performance of the BEOL memory device, as disclosed herein, can be significantly improved.

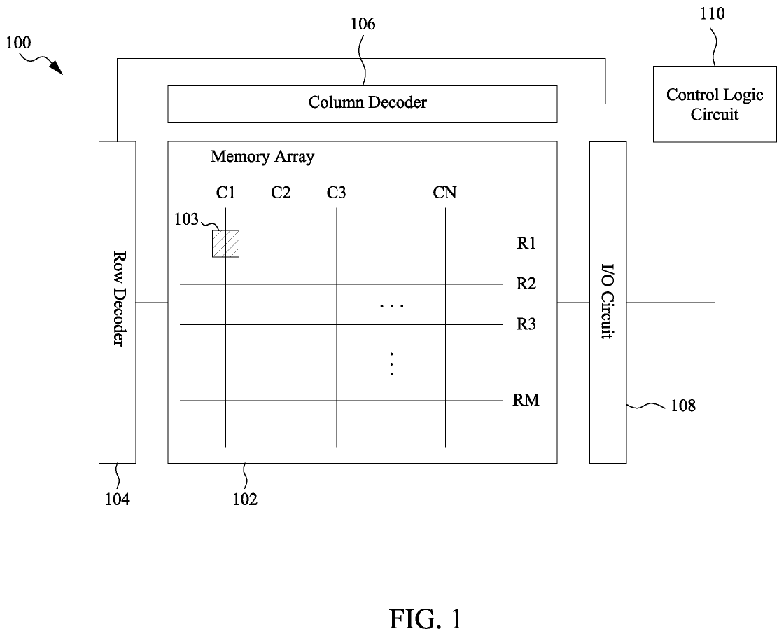

FIG. 1 illustrates an example block diagram of a semiconductor (e.g., memory) device 100, in accordance with various embodiments. In the illustrated embodiment of FIG. 1, the memory device 100 includes a memory array 102, a row decoder 104, a column decoder 106, an input/output (I/O) circuit 108, and a control logic circuit 110. Despite not being explicitly shown in FIG. 1, the components of the memory device 100 may be operatively coupled to each other and to the control logic circuit 110. For example, the control logic circuit 110, the I/O circuit 108, the column decoder 106, and the row decoder 104 may be electrically coupled to the memory array 102. Although, in the illustrated example of FIG. 1, the component are shown as separate blocks for the purpose of clear illustration, in some other embodiments, some or all of the components shown in FIG. 1 may be integrated together. For example, the memory array 102 may include an embedded I/O circuit 108.

The memory array 102 is a hardware component that stores data. In one aspect, the memory array 102 is embodied as a semiconductor memory device. The memory array 102 includes a number of memory cells (or otherwise storage units) 103. The memory array 102 includes a number of rows R₁, R₂, R₃ . . . R_{M}, each extending in a first direction (e.g., the X-direction) and a number of columns C₁, C₂, C₃ . . . C_{N}, each extending in a second direction (e.g., the Y-direction). Each of the rows/columns may include one or more conductive structures. In some embodiments, each memory cell 103 is arranged in the intersection of a corresponding row and a corresponding column and can be operated according to voltages or currents through the respective conductive structures of the column and row.

The row decoder 104 is a hardware component that can receive a row address of the memory array 102 and assert a conductive structure (e.g., a word line) at that row address. The column decoder 106 is a hardware component that can receive a column address of the memory array 102 and assert one or more conductive structures (e.g., a bit line, a source line) at that column address. The I/O circuit 108 is a hardware component that can access (e.g., read, program) each of the memory cells 103 asserted through the row decoder 104 and column decoder 106. The control logic circuit 110 is a hardware component that can control the coupled components (e.g., memory array 102 through I/O circuit 108).

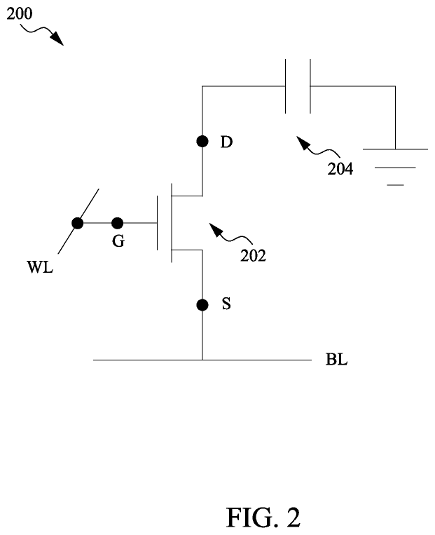

FIG. 2 illustrates an example configuration of a memory cell 200 that may be an implementation of the memory cells 103 shown in FIG. 1, in accordance with various embodiments. In the example of FIG. 2, the memory cell 200 is implemented as a one-transistor-one-capacitor (1T1C) configuration, for example, an access transistor 202 and a capacitor 204 coupled to each other in series. Specifically, the access transistor 202 may have one source/drain terminal electrically coupled to one of the terminals of the capacitor 204, and the other source/drain terminal electrically coupled to a bit line (BL), with its gate terminal electrically coupled to a word line (WL).

In some embodiments of the present disclosure, the memory cell 200 may be operatively configured as a dynamic random access memory (DRAM) cell. It, however, should be understood that the memory cell 200 can be operatively configured as any of various other memory configurations such as, for example, a ferroelectric random access memory (FeRAM) cell, a spin-transfer torque magnetic random access memory (STT-RAM) cell, a phase change random access memory (PCRAM) cell, etc., while remaining within the scope of the present disclosure.

To access (e.g., program, read) the memory cell 200, the access transistor 202 (if embodied as an n-type transistor) is turned on by applying a (e.g., voltage) signal, corresponding to a logic high state, through the word line WL, to the gate terminal of the access transistor 202. Concurrently or subsequently, a (e.g., pulse) signal is applied on the drain terminal of the access transistor 202 through the bit line BL. With the access transistor 202 turned on, the memory cell 200 is allowed to be accessed. For example, a (e.g., programming, reading) path can be provided from the bit line BL, through the access transistor 202, and to the capacitor 204.

In accordance with various embodiments of the present disclosure, the access transistor 202 and the capacitor 204 are formed on the same side of a semiconductor substrate, e.g., the frontside of a semiconductor substrate. Further, the access transistor 202 and the capacitor 204 are both formed across one or more metallization layers disposed above the frontside surface of the semiconductor substrate, e.g., M0, M1, M2, M3, M4, M5, M6, etc. Each of the metallization layers includes a number of conductor (e.g., metal) lines embedded in one or more inter-layer dielectric (ILD) or inter-metal dielectric (IMD). The ILD/IMD can include one or more of a low-k dielectric layer (i.e., a dielectric with a dielectric constant less than about 3.9), an ultra low-k dielectric layer, or an oxide (e.g., silicon oxide). Such metallization layers may be collectively referred to as a back-end-of-line (BEOL) network. Accordingly, the memory cell 200 is sometimes referred to as BEOL memory cell 200.

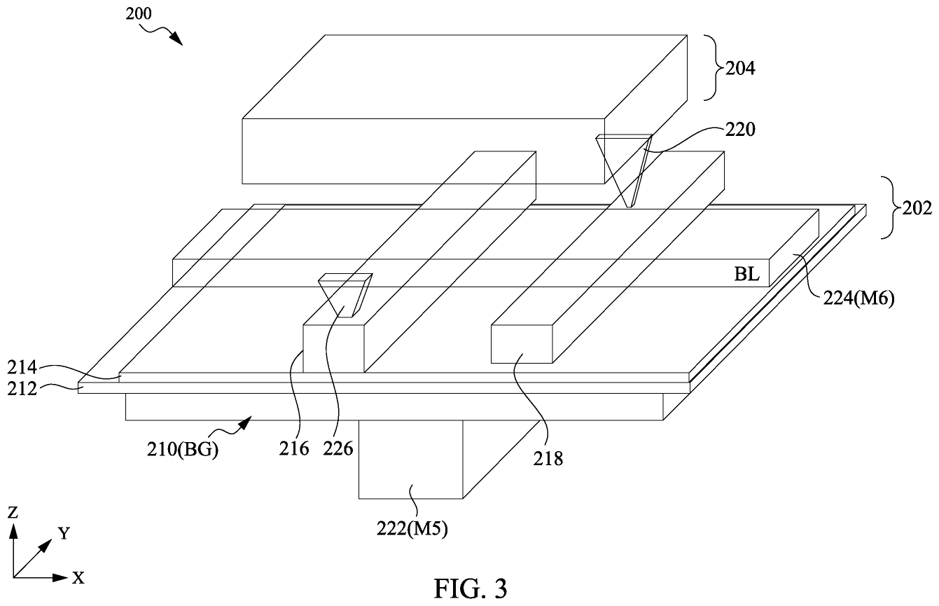

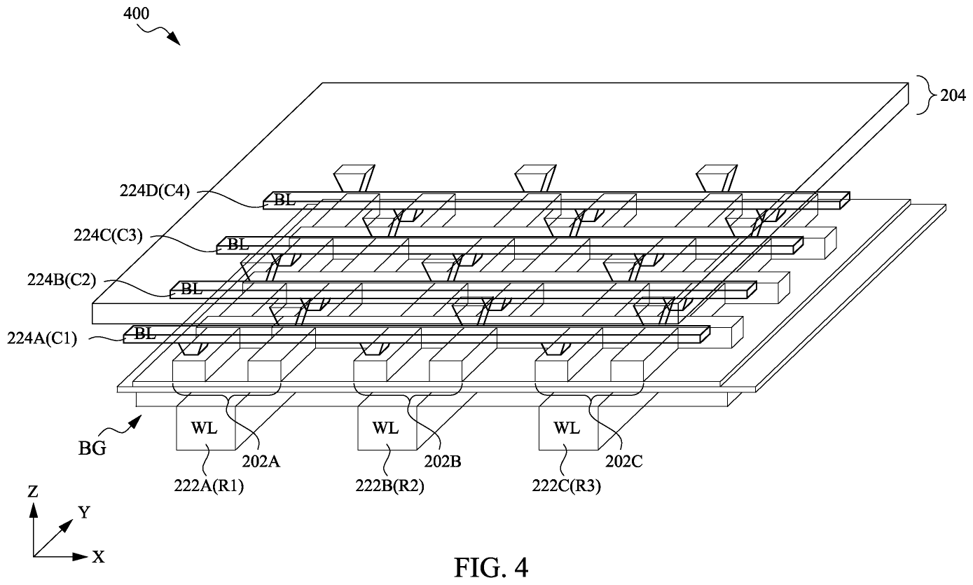

FIG. 3 illustrates a perspective view of an example configuration of such a BEOL memory cell 200 (being formed), and FIG. 4 illustrates a perspective view of a memory array 400 including a plural number of the formed BEOL memory cells 200, in accordance with various embodiments. It should be noted that the perspective views of FIGS. 3-4 are simplified, and thus, one or more components may not be expressly shown.

Referring first to FIG. 3, the access transistor 202 can be formed as a thin-film transistor (TFT) structure and, further, the access transistor 202 can be configured as a back-gate transistor, in some embodiments. For example in FIG. 3, the access transistor 202 may include a first conductor structure 210, a dielectric layer 212 disposed over the first conductor structure 210, a semiconductive-behaving layer 214 disposed over the dielectric layer 212, and a second conductor structure 216 and a third conductor structure 218 disposed over the channel layer 214. The first conductor structure 210 may operatively serve as a gate terminal of the access transistor 202 (sometimes referred to as a back gate, “BG”), the dielectric layer 212 may operatively serve as a gate dielectric of the access transistor 202, the semiconductive-behaving layer 214 may operatively serve as a channel of the access transistor 202, and the second conductor structures 216 and the third conductor structure 218 may operatively serve as a source terminal (sometime referred to as “S”) and drain terminal (sometime referred to as “D”) of the access transistor 202.

Each of the components (e.g., 210 to 218) of the access transistor 202 may be formed within one of the metallization layers or between two neighboring metallization layers, e.g., between metallization layers M5 and M6. The conductor structures 210, 216, and 218 may include tungsten, copper, gold, cobalt, ruthenium, or combinations thereof. The dielectric layer 212 may include one or more of a high-k dielectric layer (i.e., a dielectric with a dielectric constant greater than about 3.9) such as, for example, a metal oxide or a silicate of hafnium, aluminum, zirconium, lanthanum, magnesium, barium, titanium, lead, the like, or combinations thereof. The semiconductive-behaving layer 214 may include a semiconductive-behaving oxide material such as, for example, IGZO, InZnO, InSnO, SnO₂, MgAlZnO, CuO, SnO, oxides of the Delafossite group Cu—X—O with or without doping, or combinations thereof.

Although not expressly shown in FIG. 3, the capacitor 204 can be formed as a metal-insulator-metal (MIM) or metal-oxide-metal (MOM) structure disposed above the access transistor 202. The capacitor 204 may be electrically coupled to the access transistor 202 (or its drain terminal, e.g., the conductor structure 218) through a via structure 220. For example, the capacitor 204 may include a capacitor dielectric layer interposed between a bottom electrode and a top electrode. The bottom/top electrode may include tungsten, copper, gold, cobalt, ruthenium, or combinations thereof; and the capacitor dielectric layer interposed therebetween may include one or more of a high-k dielectric layer such as, for example, a metal oxide or a silicate of hafnium, aluminum, zirconium, lanthanum, magnesium, barium, titanium, lead, the like, or combinations thereof. With respect to the access transistor 202 formed between metallization layers M5 and M6, each of the components of the capacitor 204 may be formed within another of the metallization layers or between two neighboring metallization layers above metallization layer M6, e.g., between metallization layers M6 and M7.

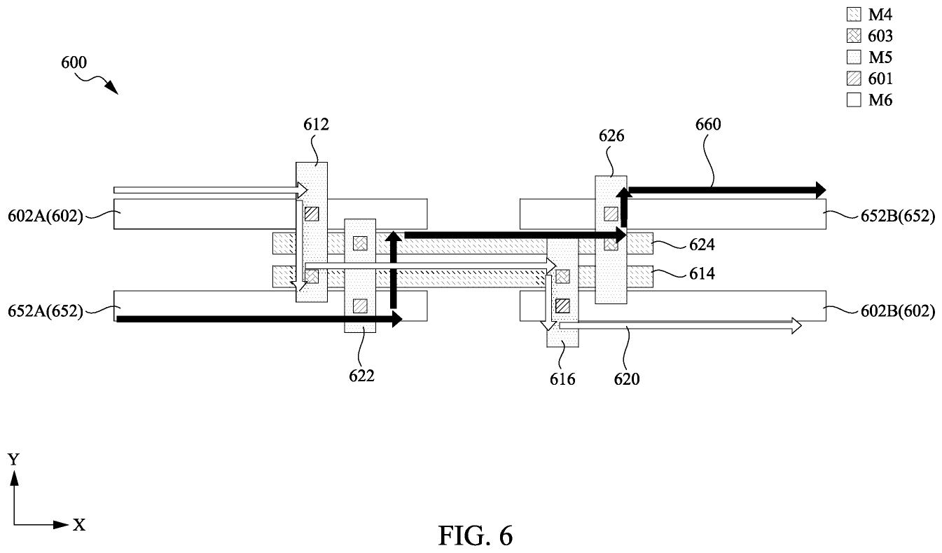

Still referring to FIG. 3, the gate terminal of the access transistor 202 (e.g., the conductor structure 210) is coupled to a WL 222 through a via structure (not shown). For example, the WL 222 may be formed within the metallization layer below the access transistor 202, e.g., metallization layer M5, and extend along a first lateral direction (e.g., the Y-direction). The source terminal of the access transistor 202 (e.g., the conductor structure 216) is coupled to a BL 224 through a via structure 226. For example in FIG. 3, the BL 224 may have at least one portion formed within the metallization layer above the transistor 202, e.g., metallization layer M6, and extending along a second lateral direction (e.g., the X-direction). According to various embodiments of the present disclosure, the BL 224 can include a plural number (e.g., 2) of end portions in one metallization layer that are physically spaced from each other but electrically coupled to each other through one or more conductor structures disposed across one or more other metallization layers, which will be discussed in further detail with respect to FIGS. 6 to 14.

Referring then to FIG. 4, the memory array 400 includes a number of such BEOL memory cells 200 that are arranged over multiple rows and columns. Respective transistors, e.g., 202A, 202B, and 202C, of some of the BEOL memory cells 200 are shown, while respective capacitors of the memory cells 200 are collectively shown as capacitor 204. The memory array 400 further includes WLs 222A, 222B, and 222C (which may correspond to rows R₁, R₂, and R₃, respectively), and BLs 224A, 224B, 224C, and 224D (which may correspond to columns C₁, C₂, C₃, and C₄, respectively). In some embodiments, the WLs, e.g., 222A to 222C, may be disposed in metallization layer M5 and extend in a first lateral direction (e.g., the Y-direction); and the BLs, e.g., 224A to 224D, may each include some portions disposed in metallization layer M6 and extending in a second lateral direction (e.g., the X-direction) perpendicular to the first lateral direction. In the example embodiment of FIG. 4, the memory cells of the memory array 400 may share a common back gate BG, with each subset of the memory cells disposed along a corresponding row sharing a common WL and each subset of the memory cells disposed along a corresponding column sharing a common BL.

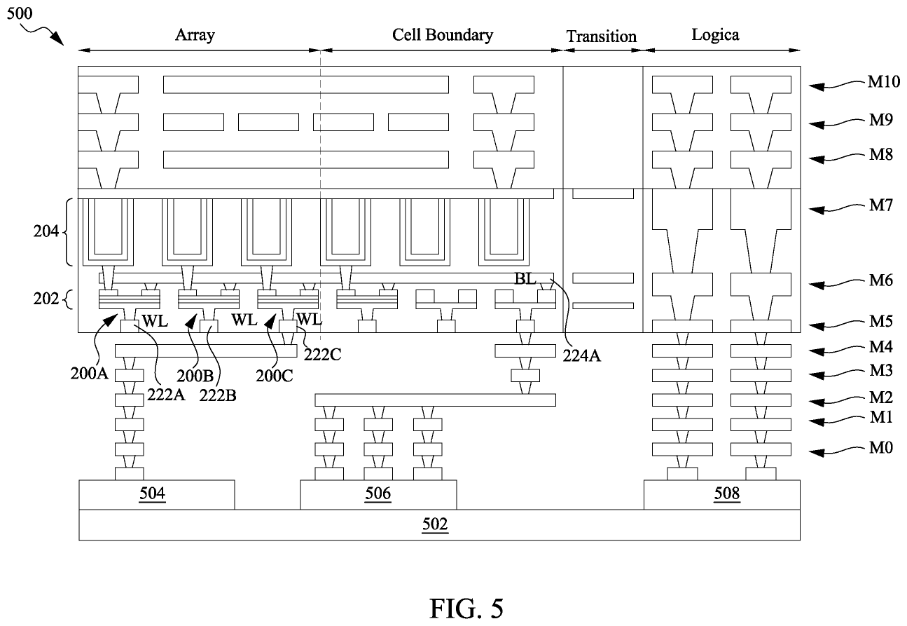

FIG. 5 illustrates a cross-sectional view of a memory device 500 (being formed) including a plural number of the BEOL memory cells 200 discussed above with respect to FIGS. 2-4, in accordance with various embodiments. For example, the memory device 500 can include the memory array 400 of FIG. 4. Further, the memory device 500 can include a number of other structures operatively serve as the components discussed in FIG. 1, e.g., I/O circuit 108, control logic circuit 110, etc.

As shown, the memory device 500 may be divided into a number of portions/sections laterally arranged with respect to one another, e.g., an array portion, a boundary portion, a transition portion, and a logic portion. These portions may be formed over a substrate 502. Along a major surface of the substrate 502, a number of first transistors 504, second transistors 506, and third transistors 508 are formed in the array portion, the boundary portion, and the logic portion, respectively. The transistors 504 to 508 may form a part of a front-end-of-line (FEOL) network. Over the FEOL network, the memory device 500 includes a number of metallization layers, e.g., M0, M1, M2, M4, M5, M6, M7, M8, M9, and M10, formed as a part of a back-end-of-line (BEOL) network.

In the array portion, the memory device 500 may include a number of BEOL memory cells, e.g., 200A, 200B, 200C, etc. Each of the memory cells 200A-C consists of a respective transistor 202 formed between metallization layers M5 and M6, and a respective capacitor 204 formed between metallization layers M6 and M7. In some embodiments, the BEOL memory cells can be formed as a memory array, which can be operatively accessed through WLs, e.g., 222A, 222B, 222C, etc., and BLs, e.g., 224A, etc. In the cross-sectional view of FIG. 5, the WLs 222A-C are disposed in metallization layer M5, and the BL 224A is disposed in metallization layer M6. However, the BL 224A (and other BLs) may have its end portions disposed in metallization layer M6 and further have some other portions disposed in other metallization layers, which causes the BLs to twist with each other, according to various embodiments of the preset disclosure. Further, the first transistors 504, configured in the array portion, may operatively serve as one or more WL drivers for the memory array (e.g., part of the row decoder 104 of FIG. 1). The second transistors 506, configured in the boundary portion, may operatively serve as one or more sending amplifiers for the memory array (e.g., part of the I/O circuit 108 of FIG. 1). The third transistors 508, configured in the logic portion, may operatively serve as one or more control circuits for the memory array (e.g., part of the control logic circuit 110 of FIG. 1)

FIG. 6 illustrates an example layout 600 including a first BL 602 and a second BL 652 arranged in a twisted manner, e.g., with one or more their respective portions overlapped with each other (when viewed from the top), in accordance with some embodiments. Each of the first BL 602 and second BL 652 may be operatively coupled to a corresponding number of BEOL memory cells (e.g., 200 of FIG. 2).

As shown, the first BL 602 includes a first end portion 602A and a second end portion 602B spaced from each other, and the second BL 652 includes a first end portion 652A and a second end portion 652B spaced from each other. Each of the first end portions, 602A and 652A, and second end portions, 602B and 652B, extends along the X-direction. Further, the first end portion 602A (of the first BL 602) is spaced from a projection of the second end portion 602B (of the first BL 602) along the Y-direction, and the first end portion 652A (of the second BL 652) is spaced from a projection of the second end portion 652B (of the second BL 652) along the Y-direction. Stated another way, the first end portion 602A and the projection of the second end portion 602B are in parallel with each other, and the first end portion 652A and the projection of the second end portion 652B are in parallel with each other.

Regarding the first BL 602, the first end portion 602A and the second end portion 602B, even physically separated in the same metallization layer M6, may be electrically coupled to each other through a number of conductor structures disposed in one or more metallization layers. For example, the first end portion 602A is coupled to a conductor structure 612 (disposed in metallization layer M5) through one of via structures 601, the conductor structure 612 is coupled to a conductor structure 614 (disposed in metallization layer M4) through one of via structures 603, the conductor structure 614 is coupled to a conductor structure 616 (disposed in metallization layer M5) through another one of the via structures 603, and the conductor structure 616 is coupled to the second end portion 602B through another one of the via structures 601.

As such, an electrical path 620 can be formed at least by the first end portion 602A in metallization layer M6, the conductor structure 612 in metallization layer M5, the conductor structure 614 in metallization layer M4, the conductor structure 616 again in metallization layer M5, and the second end portion 602B again in metallization layer M6. In some embodiments, the electrical path 620 may be operatively equivalent to the first BL 602. Alternatively stated, the first BL 602 can operatively include the first end portion 602A, the conductor structure 612, the conductor structure 614, the conductor structure 616, and the second end portion 602B.

Regarding the second BL 652, the first end portion 652A and the second end portion 652B, even physically separated in the same metallization layer M6, may be electrically coupled to each other through a number of conductor structures disposed in one or more metallization layers. For example, the first end portion 652A is coupled to a conductor structure 622 (disposed in metallization layer M5) through one of via structures 601, the conductor structure 622 is coupled to a conductor structure 624 (disposed in metallization layer M4) through one of via structures 603, the conductor structure 624 is coupled to a conductor structure 626 (disposed in metallization layer M5) through another one of the via structures 603, and the conductor structure 626 is coupled to the second end portion 652B through another one of the via structures 601.

As such, an electrical path 660 can be formed at least by the first end portion 652A in metallization layer M6, the conductor structure 622 in metallization layer M5, the conductor structure 624 in metallization layer M4, the conductor structure 626 again in metallization layer M5, and the second end portion 652B again in metallization layer M6. In some embodiments, the electrical path 660 may be operatively equivalent to the second BL 652. Alternatively stated, the second BL 652 can operatively include the first end portion 652A, the conductor structure 622, the conductor structure 624, the conductor structure 626, and the second end portion 652B.

In the embodiment of FIG. 6, the conductor structures formed in the metallization layer M6 (e.g., 602A, 602B, 652A, 652B) may extend along the X-direction, the conductor structures formed in the metallization layer M5 (e.g., 612, 622, 616, 626) may extend along the Y-direction, and the conductor structures formed in the metallization layer M4 (e.g., 614, 624) may extend along the X-direction. With one or more “intermediate” portions disposed in the metallization layers and extending in the directions different from the end portions, different BLs, e.g., 602 (or equivalent path 620) and 652 (or equivalent path 660), can be twisted.

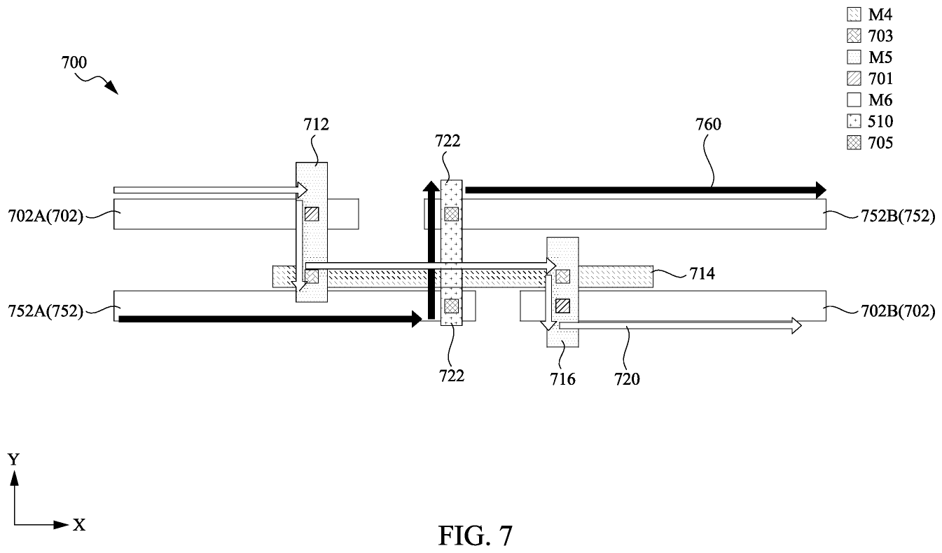

FIG. 7 illustrates an example layout 700 including a first BL 702 and a second BL 752 arranged in a twisted manner, e.g., with one or more their respective portions overlapped with each other (when viewed from the top), in accordance with some embodiments. Each of the first BL 702 and second BL 752 may be operatively coupled to a corresponding number of BEOL memory cells (e.g., 200 of FIG. 2).

As shown, the first BL 702 includes a first end portion 702A and a second end portion 702B spaced from each other, and the second BL 752 includes a first end portion 752A and a second end portion 752B spaced from each other. Each of the first end portions, 702A and 752A, and second end portions, 702B and 752B, extends along the X-direction. Further, the first end portion 702A (of the first BL 702) is spaced from a projection of the second end portion 702B (of the first BL 702) along the Y-direction, and the first end portion 752A (of the second BL 752) is spaced from a projection of the second end portion 752B (of the second BL 752) along the Y-direction. Stated another way, the first end portion 702A and the projection of the second end portion 702B are in parallel with each other, and the first end portion 752A and the projection of the second end portion 752B are in parallel with each other.

Regarding the first BL 702, the first end portion 702A and the second end portion 702B, even physically separated in the same metallization layer M6, may be electrically coupled to each other through a number of conductor structures disposed in one or more metallization layers. For example, the first end portion 702A is coupled to a conductor structure 712 (disposed in metallization layer M5) through one of via structures 701, the conductor structure 712 is coupled to a conductor structure 714 (disposed in metallization layer M4) through one of via structures 703, the conductor structure 714 is coupled to a conductor structure 716 (disposed in metallization layer M5) through another one of the via structures 703, and the conductor structure 716 is coupled to the second end portion 702B through another one of the via structures 701.

As such, an electrical path 720 can be formed at least by the first end portion 702A in metallization layer M6, the conductor structure 712 in metallization layer M5, the conductor structure 714 in metallization layer M4, the conductor structure 716 again in metallization layer M5, and the second end portion 702B again in metallization layer M6. In some embodiments, the electrical path 720 may be operatively equivalent to the first BL 702. Alternatively stated, the first BL 702 can operatively include the first end portion 702A, the conductor structure 712, the conductor structure 714, the conductor structure 716, and the second end portion 702B.

Regarding the second BL 752, the first end portion 752A and the second end portion 752B, even physically separated in the same metallization layer M6, may be electrically coupled to each other through a number of conductor structures disposed in one or more metallization layers. For example, the first end portion 752A is coupled to a conductor structure 722 (disposed between metallization layers M5 and M6) through one of via structures 705, and the conductor structure 722 is coupled to the second end portion 752B through another one of the via structures 705. In some embodiments, the conductor structure 722 may serve as a source or drain terminal (e.g., 216, 218 of FIG. 2) of one or more BEOL memory cells.

As such, an electrical path 760 can be formed at least by the first end portion 752A in metallization layer M6, the conductor structure 722 between metallization layers M5 and M6, and the second end portion 752B again in metallization layer M6. In some embodiments, the electrical path 760 may be operatively equivalent to the second BL 752. Alternatively stated, the second BL 752 can operatively include the first end portion 752A, the conductor structure 722, and the second end portion 752B.

In the embodiment of FIG. 7, the conductor structures formed in the metallization layer M6 (e.g., 702A, 702B, 752A, 752B) may extend along the X-direction, the conductor structures formed in the metallization layer M5 (e.g., 712, 716) may extend along the Y-direction, the conductor structures formed in the metallization layer M4 (e.g., 714) may extend along the X-direction, and the conductor structures formed between the metallization layers M5 and M6 (e.g., 722) may extend along the Y-direction. With one or more “intermediate” portions disposed in the metallization layers and extending in the directions different from the end portions, different BLs, e.g., 702 (or equivalent path 720) and 752 (or equivalent path 760), can be twisted.

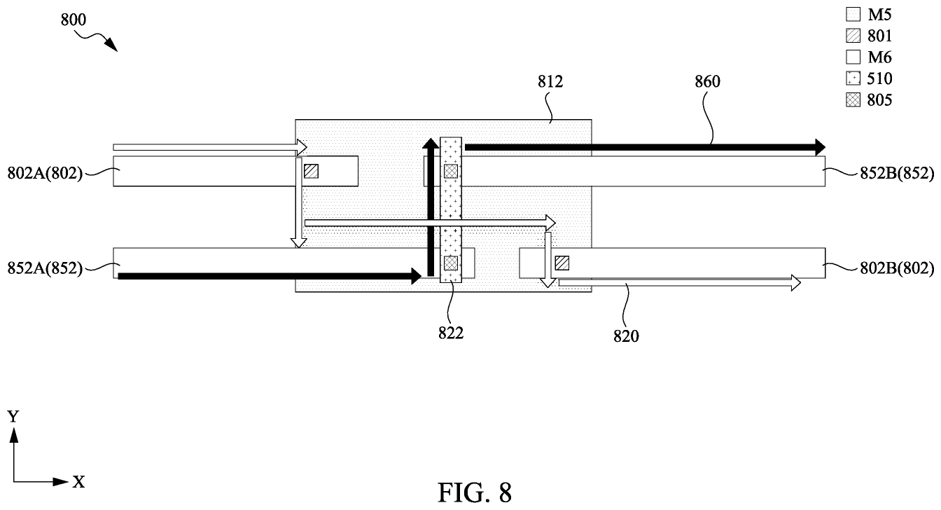

FIG. 8 illustrates an example layout 800 including a first BL 802 and a second BL 852 arranged in a twisted manner, e.g., with one or more their respective portions overlapped with each other (when viewed from the top), in accordance with some embodiments. Each of the first BL 802 and second BL 852 may be operatively coupled to a corresponding number of BEOL memory cells (e.g., 200 of FIG. 2).

As shown, the first BL 802 includes a first end portion 802A and a second end portion 802B spaced from each other, and the second BL 852 includes a first end portion 852A and a second end portion 852B spaced from each other. Each of the first end portions, 802A and 852A, and second end portions, 802B and 852B, extends along the X-direction. Further, the first end portion 802A (of the first BL 802) is spaced from a projection of the second end portion 802B (of the first BL 802) along the Y-direction, and the first end portion 852A (of the second BL 852) is spaced from a projection of the second end portion 852B (of the second BL 852) along the Y-direction. Stated another way, the first end portion 802A and the projection of the second end portion 802B are in parallel with each other, and the first end portion 852A and the projection of the second end portion 852B are in parallel with each other.

Regarding the first BL 802, the first end portion 802A and the second end portion 802B, even physically separated in the same metallization layer M6, may be electrically coupled to each other through a number of conductor structures disposed in one or more metallization layers. For example, the first end portion 802A is coupled to a conductor structure 812 (disposed in metallization layer M5) through one of via structures 801, and the conductor structure 812 is coupled to the second end portion 802B through another one of the via structures 801.

As such, an electrical path 820 can be formed at least by the first end portion 802A in metallization layer M6, the conductor structure 812 in metallization layer M5, and the second end portion 802B again in metallization layer M6. In some embodiments, the electrical path 820 may be operatively equivalent to the first BL 802. Alternatively stated, the first BL 802 can operatively include the first end portion 802A, the conductor structure 812, and the second end portion 802B.

Regarding the second BL 852, the first end portion 852A and the second end portion 852B, even physically separated in the same metallization layer M6, may be electrically coupled to each other through a number of conductor structures disposed in one or more metallization layers. For example, the first end portion 852A is coupled to a conductor structure 822 (disposed between metallization layers M5 and M6) through one of via structures 805, and the conductor structure 822 is coupled to the second end portion 852B through another one of the via structures 805. In some embodiments, the conductor structure 822 may serve as a source or drain terminal (e.g., 216, 218 of FIG. 2) of one or more BEOL memory cells.

As such, an electrical path 860 can be formed at least by the first end portion 852A in metallization layer M6, the conductor structure 822 between metallization layers M5 and M6, and the second end portion 852B again in metallization layer M6. In some embodiments, the electrical path 860 may be operatively equivalent to the second BL 852. Alternatively stated, the second BL 852 can operatively include the first end portion 852A, the conductor structure 822, and the second end portion 852B.

In the embodiment of FIG. 8, the conductor structures formed in the metallization layer M6 (e.g., 802A, 802B, 852A, 852B) may extend along the X-direction, the conductor structures formed in the metallization layer M5 (e.g., 812) may be formed as an island spanning along both the X-direction and Y-direction, and the conductor structures formed between the metallization layers M5 and M6 (e.g., 822) may extend along the Y-direction. With one or more “intermediate” portions disposed in the metallization layers and extending in the directions different from the end portions, different BLs, e.g., 802 (or equivalent path 820) and 852 (or equivalent path 860), can be twisted.

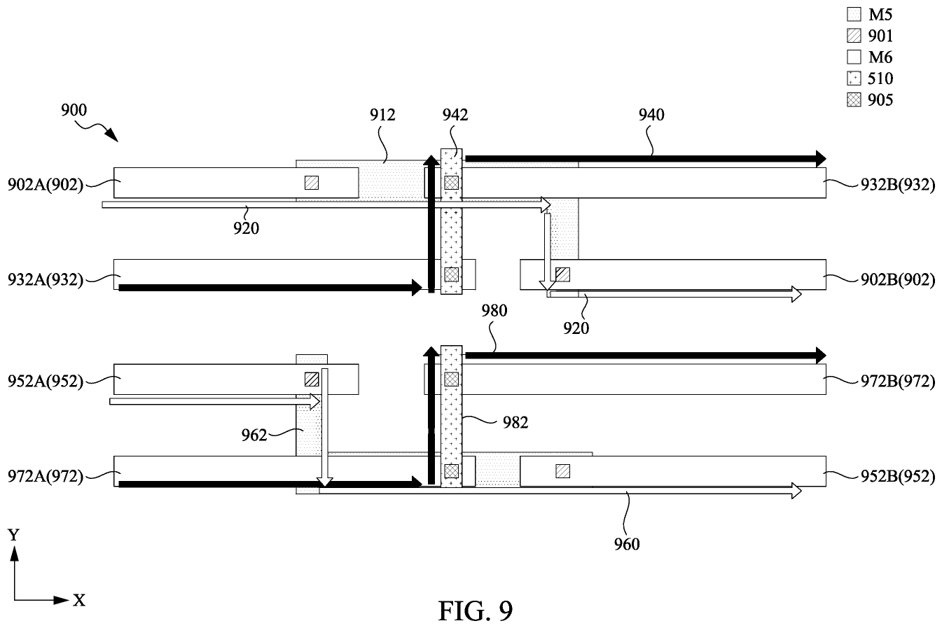

FIG. 9 illustrates an example layout 900 including a first BL 902, a second BL 932, a third BL 952, and a fourth BL 972 arranged in a twisted manner, e.g., with one or more their respective portions overlapped with each other (when viewed from the top), in accordance with some embodiments. Each of the first BL 902, second BL 932, third BL 952, and fourth BL 972 may be operatively coupled to a corresponding number of BEOL memory cells (e.g., 200 of FIG. 2).

As shown, the first BL 902 includes a first end portion 902A and a second end portion 902B spaced from each other, the second BL 932 includes a first end portion 932A and a second end portion 932B spaced from each other, the third BL 952 includes a first end portion 952A and a second end portion 952B spaced from each other, and the fourth BL 972 includes a first end portion 972A and a second end portion 972B spaced from each other. Each of the first end portions, 902A, 932A, 952A, and 972A, and second end portions, 902B, 932B, 952B, and 972B, extends along the X-direction. Further, the first end portion 902A (of the first BL 902) is spaced from a projection of the second end portion 902B (of the first BL 902) along the Y-direction, with other BLs configured similarly.

Regarding the first BL 902, the first end portion 902A and the second end portion 902B, even physically separated in the same metallization layer M6, may be electrically coupled to each other through a number of conductor structures disposed in one or more metallization layers. For example, the first end portion 902A is coupled to a conductor structure 912 (disposed in metallization layer M5) through one of via structures 901, and the conductor structure 912 is coupled to the second end portion 902B through another one of the via structures 901.

As such, an electrical path 920 can be formed at least by the first end portion 902A in metallization layer M6, the conductor structure 912 in metallization layer M5, and the second end portion 902B again in metallization layer M6. In some embodiments, the electrical path 920 may be operatively equivalent to the first BL 902. Alternatively stated, the first BL 902 can operatively include the first end portion 902A, the conductor structure 912, and the second end portion 902B.

Regarding the second BL 932, the first end portion 932A and the second end portion 932B, even physically separated in the same metallization layer M6, may be electrically coupled to each other through a number of conductor structures disposed in one or more metallization layers. For example, the first end portion 932A is coupled to a conductor structure 942 (disposed between metallization layers M5 and M6) through one of via structures 905, and the conductor structure 942 is coupled to the second end portion 932B through another one of the via structures 905. In some embodiments, the conductor structure 942 may serve as a source or drain terminal (e.g., 216, 218 of FIG. 2) of one or more BEOL memory cells.

As such, an electrical path 940 can be formed at least by the first end portion 932A in metallization layer M6, the conductor structure 942 between metallization layers M5 and M6, and the second end portion 932B again in metallization layer M6. In some embodiments, the electrical path 940 may be operatively equivalent to the second BL 932. Alternatively stated, the second BL 932 can operatively include the first end portion 932A, the conductor structure 942, and the second end portion 932B.

Regarding the third BL 952, the first end portion 952A and the second end portion 952B, even physically separated in the same metallization layer M6, may be electrically coupled to each other through a number of conductor structures disposed in one or more metallization layers. For example, the first end portion 952A is coupled to a conductor structure 962 (disposed in metallization layer M5) through one of the via structures 901, and the conductor structure 962 is coupled to the second end portion 952B through another one of the via structures 901.

As such, an electrical path 960 can be formed at least by the first end portion 952A in metallization layer M6, the conductor structure 962 in metallization layer M5, and the second end portion 952B again in metallization layer M6. In some embodiments, the electrical path 960 may be operatively equivalent to the third BL 952. Alternatively stated, the third BL 952 can operatively include the first end portion 952A, the conductor structure 962, and the second end portion 952B.

Regarding the fourth BL 972, the first end portion 972A and the second end portion 972B, even physically separated in the same metallization layer M6, may be electrically coupled to each other through a number of conductor structures disposed in one or more metallization layers. For example, the first end portion 972A is coupled to a conductor structure 982 (disposed between metallization layers M5 and M6) through one of the via structures 905, and the conductor structure 982 is coupled to the second end portion 972B through another one of the via structures 905. In some embodiments, the conductor structure 982 may serve as a source or drain terminal (e.g., 216, 218 of FIG. 2) of one or more BEOL memory cells.

As such, an electrical path 980 can be formed at least by the first end portion 972A in metallization layer M6, the conductor structure 982 between metallization layers M5 and M6, and the second end portion 972B again in metallization layer M6. In some embodiments, the electrical path 980 may be operatively equivalent to the fourth BL 972. Alternatively stated, the fourth BL 972 can operatively include the first end portion 972A, the conductor structure 982, and the second end portion 972B.

In the embodiment of FIG. 9, the conductor structures formed in the metallization layer M6 (e.g., 902A, 902B, 932A, 932B, 952A, 952B, 972A, 972B) may extend along the X-direction, the conductor structures formed in the metallization layer M5 (e.g., 912, 962) may each be formed in an L-shaped profile which consists of a first portion extending along the X-direction and a second portion extending along the Y-direction, and the conductor structures formed between the metallization layers M5 and M6 (e.g., 942, 982) may extend along the Y-direction. With one or more “intermediate” portions disposed in the metallization layers and extending in the directions different from the end portions, different BLs, e.g., 902 (or equivalent path 920), 932 (or equivalent path 940), 952 (or equivalent path 960), and 972 (or equivalent path 980), can be twisted.

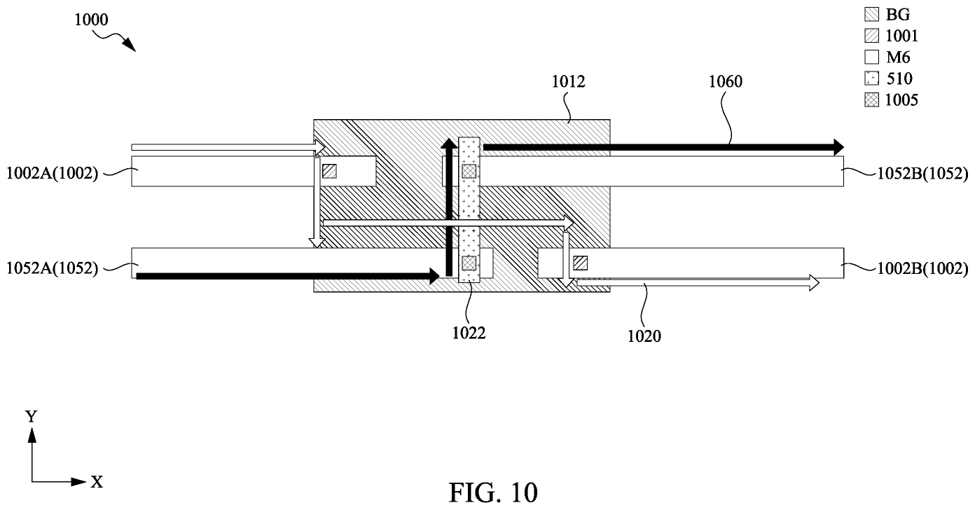

FIG. 10 illustrates an example layout 1000 including a first BL 1002 and a second BL 1052 arranged in a twisted manner, e.g., with one or more their respective portions overlapped with each other (when viewed from the top), in accordance with some embodiments. Each of the first BL 1002 and second BL 1052 may be operatively coupled to a corresponding number of BEOL memory cells (e.g., 200 of FIG. 2).

As shown, the first BL 1002 includes a first end portion 1002A and a second end portion 1002B spaced from each other, and the second BL 1052 includes a first end portion 1052A and a second end portion 1052B spaced from each other. Each of the first end portions, 1002A and 1052A, and second end portions, 1002B and 1052B, extends along the X-direction. Further, the first end portion 1002A (of the first BL 1002) is spaced from a projection of the second end portion 1002B (of the first BL 1002) along the Y-direction, and the first end portion 1052A (of the second BL 1052) is spaced from a projection of the second end portion 1052B (of the second BL 1052) along the Y-direction. Stated another way, the first end portion 1002A and the projection of the second end portion 1002B are in parallel with each other, and the first end portion 1052A and the projection of the second end portion 1052B are in parallel with each other.

Regarding the first BL 1002, the first end portion 1002A and the second end portion 1002B, even physically separated in the same metallization layer M6, may be electrically coupled to each other through a number of conductor structures disposed in one or more metallization layers. For example, the first end portion 1002A is coupled to a conductor structure 1012 (disposed between metallization layers M5 and M6) through one of via structures 1001, and the conductor structure 1012 is coupled to the second end portion 1002B through another one of the via structures 1001. In some embodiments, the conductor structure 1012 may serve as a gate terminal, or BG, (e.g., 210 of FIG. 2) of one or more BEOL memory cells.

As such, an electrical path 1020 can be formed at least by the first end portion 1002A in metallization layer M6, the conductor structure 1012 between metallization layers M5 and M6, and the second end portion 1002B again in metallization layer M6. In some embodiments, the electrical path 1020 may be operatively equivalent to the first BL 1002. Alternatively stated, the first BL 1002 can operatively include the first end portion 1002A, the conductor structure 1012, and the second end portion 1002B.

Regarding the second BL 1052, the first end portion 1052A and the second end portion 1052B, even physically separated in the same metallization layer M6, may be electrically coupled to each other through a number of conductor structures disposed in one or more metallization layers. For example, the first end portion 1052A is coupled to a conductor structure 1022 (disposed between metallization layers M5 and M6) through one of via structures 1005, and the conductor structure 1022 is coupled to the second end portion 1052B through another one of the via structures 1005. In some embodiments, the conductor structure 1022 may serve as a source or drain terminal (e.g., 216, 218 of FIG. 2) of one or more BEOL memory cells.

As such, an electrical path 1060 can be formed at least by the first end portion 1052A in metallization layer M6, the conductor structure 1022 between metallization layers M5 and M6, and the second end portion 1052B again in metallization layer M6. In some embodiments, the electrical path 1060 may be operatively equivalent to the second BL 1052. Alternatively stated, the second BL 1052 can operatively include the first end portion 1052A, the conductor structure 1022, and the second end portion 1052B.

In the embodiment of FIG. 10, the conductor structures formed in the metallization layer M6 (e.g., 1002A, 1002B, 1052A, 1052B) may extend along the X-direction, the conductor structures formed between the metallization layers M5 and M6 (e.g., 1012) may be formed as an island spanning along both the X-direction and Y-direction, and the other conductor structures formed between the metallization layers M5 and M6 (e.g., 1022) may extend along the Y-direction. With one or more “intermediate” portions disposed in the metallization layers and extending in the directions different from the end portions, different BLs, e.g., 1002 (or equivalent path 1020) and 1052 (or equivalent path 1060), can be twisted.

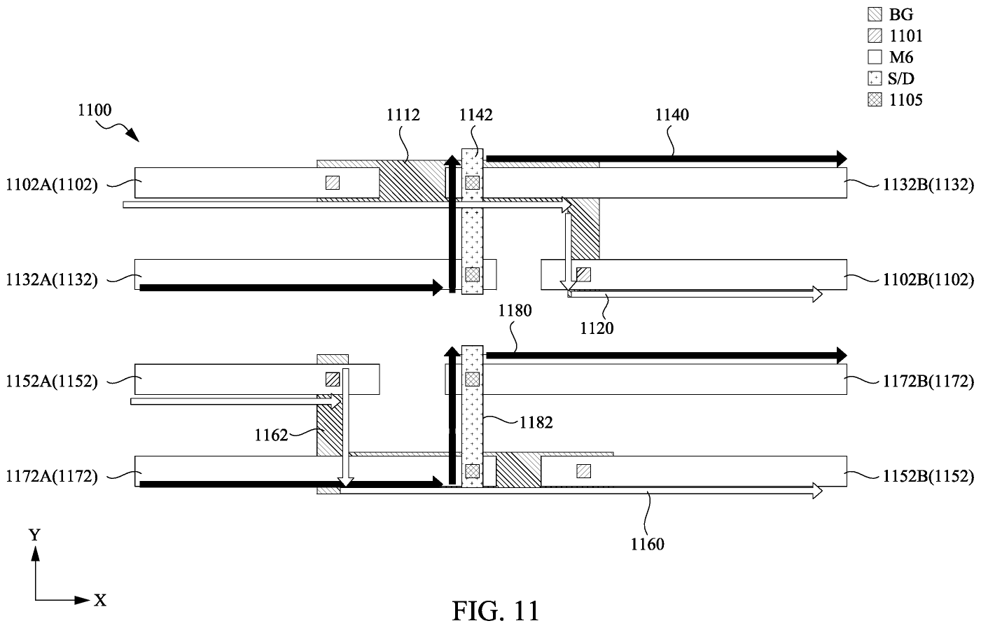

FIG. 11 illustrates an example layout 1100 including a first BL 1102, a second BL 1132, a third BL 1152, and a fourth BL 1172 arranged in a twisted manner, e.g., with one or more their respective portions overlapped with each other (when viewed from the top), in accordance with some embodiments. Each of the first BL 1102, second BL 1132, third BL 1152, and fourth BL 1172 may be operatively coupled to a corresponding number of BEOL memory cells (e.g., 200 of FIG. 2).

As shown, the first BL 1102 includes a first end portion 1102A and a second end portion 1102B spaced from each other, the second BL 1132 includes a first end portion 1132A and a second end portion 1132B spaced from each other, the third BL 1152 includes a first end portion 1152A and a second end portion 1152B spaced from each other, and the fourth BL 1172 includes a first end portion 1172A and a second end portion 1172B spaced from each other. Each of the first end portions, 1102A, 1132A, 1152A, and 1172A, and second end portions, 1102B, 1132B, 1152B, and 1172B, extends along the X-direction. Further, the first end portion 1102A (of the first BL 1102) is spaced from a projection of the second end portion 1102B (of the first BL 1102) along the Y-direction, with other BLs configured similarly.

Regarding the first BL 1102, the first end portion 1102A and the second end portion 1102B, even physically separated in the same metallization layer M6, may be electrically coupled to each other through a number of conductor structures disposed in one or more metallization layers. For example, the first end portion 1102A is coupled to a conductor structure 1112 (disposed between metallization layers M5 and M6) through one of via structures 1101, and the conductor structure 1112 is coupled to the second end portion 1102B through another one of the via structures 1101. In some embodiments, the conductor structure 1112 may serve as a gate terminal, or BG, (e.g., 210 of FIG. 2) of one or more BEOL memory cells.

As such, an electrical path 1120 can be formed at least by the first end portion 1102A in metallization layer M6, the conductor structure 1112 between metallization layers M5 and M6, and the second end portion 1102B again in metallization layer M6. In some embodiments, the electrical path 1120 may be operatively equivalent to the first BL 1102. Alternatively stated, the first BL 1102 can operatively include the first end portion 1102A, the conductor structure 1112, and the second end portion 1102B.

Regarding the second BL 1132, the first end portion 1132A and the second end portion 1132B, even physically separated in the same metallization layer M6, may be electrically coupled to each other through a number of conductor structures disposed in one or more metallization layers. For example, the first end portion 1132A is coupled to a conductor structure 1142 (disposed between metallization layers M5 and M6) through one of via structures 1105, and the conductor structure 1142 is coupled to the second end portion 1132B through another one of the via structures 1105. In some embodiments, the conductor structure 1142 may serve as a source or drain terminal (e.g., 216, 218 of FIG. 2) of one or more BEOL memory cells.

As such, an electrical path 1140 can be formed at least by the first end portion 1132A in metallization layer M6, the conductor structure 1142 between metallization layers M5 and M6, and the second end portion 1132B again in metallization layer M6. In some embodiments, the electrical path 1140 may be operatively equivalent to the second BL 1132. Alternatively stated, the second BL 1132 can operatively include the first end portion 1132A, the conductor structure 1142, and the second end portion 1132B.

Regarding the third BL 1152, the first end portion 1152A and the second end portion 1152B, even physically separated in the same metallization layer M6, may be electrically coupled to each other through a number of conductor structures disposed in one or more metallization layers. For example, the first end portion 1152A is coupled to a conductor structure 1162 (disposed between metallization layers M5 and M6) through one of the via structures 1101, and the conductor structure 1162 is coupled to the second end portion 1152B through another one of the via structures 1101. In some embodiments, the conductor structure 1162 may serve as a gate terminal, or BG, (e.g., 210 of FIG. 2) of one or more BEOL memory cells.

As such, an electrical path 1160 can be formed at least by the first end portion 1152A in metallization layer M6, the conductor structure 1162 in metallization layer M5, and the second end portion 1152B again in metallization layer M6. In some embodiments, the electrical path 1160 may be operatively equivalent to the third BL 1152. Alternatively stated, the third BL 1152 can operatively include the first end portion 1152A, the conductor structure 1162, and the second end portion 1152B.

Regarding the fourth BL 1172, the first end portion 1172A and the second end portion 1172B, even physically separated in the same metallization layer M6, may be electrically coupled to each other through a number of conductor structures disposed in one or more metallization layers. For example, the first end portion 1172A is coupled to a conductor structure 1182 (disposed between metallization layers M5 and M6) through one of the via structures 1105, and the conductor structure 1182 is coupled to the second end portion 1172B through another one of the via structures 1105. In some embodiments, the conductor structure 1182 may serve as a source or drain terminal (e.g., 216, 218 of FIG. 2) of one or more BEOL memory cells.

As such, an electrical path 1180 can be formed at least by the first end portion 1172A in metallization layer M6, the conductor structure 1182 between metallization layers M5 and M6, and the second end portion 1172B again in metallization layer M6. In some embodiments, the electrical path 1180 may be operatively equivalent to the fourth BL 1172. Alternatively stated, the fourth BL 1172 can operatively include the first end portion 1172A, the conductor structure 1182, and the second end portion 1172B.

In the embodiment of FIG. 11, the conductor structures formed in the metallization layer M6 (e.g., 1102A, 1102B, 1132A, 1132B, 1152A, 1152B, 1172A, 1172B) may extend along the X-direction, the conductor structures formed between the metallization layers M5 and M6 (e.g., 1112, 1162) may each be formed in an L-shaped profile which consists of a first portion extending along the X-direction and a second portion extending along the Y-direction, and the conductor structures formed between the metallization layers M5 and M6 (e.g., 1142, 1182) may extend along the Y-direction. With one or more “intermediate” portions disposed in the metallization layers and extending in the directions different from the end portions, different BLs, e.g., 1102 (or equivalent path 1120), 1132 (or equivalent path 1140), 1152 (or equivalent path 1160), and 1172 (or equivalent path 1180), can be twisted.

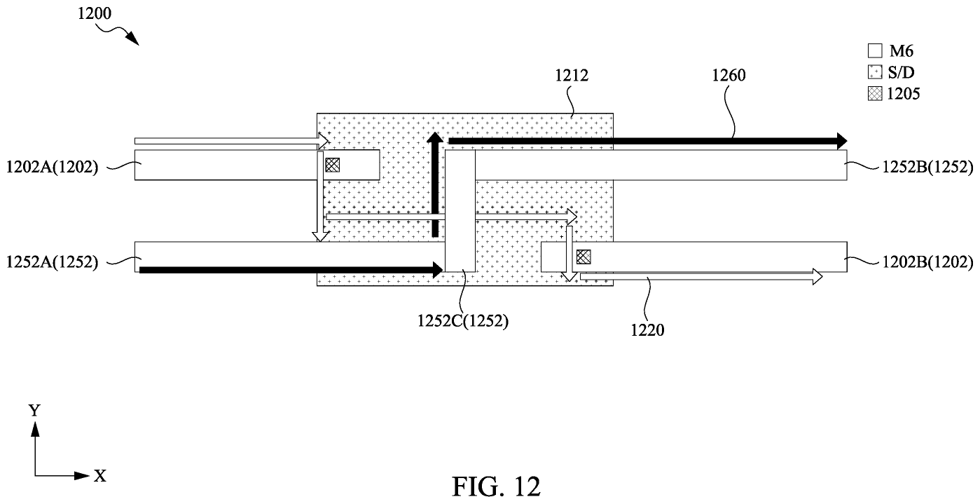

FIG. 12 illustrates an example layout 1200 including a first BL 1202 and a second BL 1252 arranged in a twisted manner, e.g., with one or more their respective portions overlapped with each other (when viewed from the top), in accordance with some embodiments. Each of the first BL 1202 and second BL 1252 may be operatively coupled to a corresponding number of BEOL memory cells (e.g., 200 of FIG. 2).

As shown, the first BL 1202 includes a first end portion 1202A and a second end portion 1202B spaced from each other, and the second BL 1252 includes a first end portion 1252A, a second end portion 1252B, and a third portion 1252C connecting the first end portion 1252A and second end portion 1252B. Each of the first end portions, 1202A and 1252A, and second end portions, 1202B and 1252B, extends along the X-direction, while the third portion 1252C extends along the Y-direction. Further, the first end portion 1202A (of the first BL 1202) is spaced from a projection of the second end portion 1202B (of the first BL 1202) along the Y-direction, and the first end portion 1252A (of the second BL 1252) is spaced from a projection of the second end portion 1252B (of the second BL 1252) along the Y-direction.

Regarding the first BL 1202, the first end portion 1202A and the second end portion 1202B, even physically separated in the same metallization layer M6, may be electrically coupled to each other through a number of conductor structures disposed in one or more metallization layers. For example, the first end portion 1202A is coupled to a conductor structure 1212 (disposed between metallization layers M5 and M6) through one of via structures 1205, and the conductor structure 1212 is coupled to the second end portion 1202B through another one of the via structures 1205. In some embodiments, the conductor structure 1212 may serve as a source or drain terminal (e.g., 216, 218 of FIG. 2) of one or more BEOL memory cells.

As such, an electrical path 1220 can be formed at least by the first end portion 1202A in metallization layer M6, the conductor structure 1212 between metallization layers M5 and M6, and the second end portion 1202B again in metallization layer M6. In some embodiments, the electrical path 1220 may be operatively equivalent to the first BL 1202. Alternatively stated, the first BL 1202 can operatively include the first end portion 1202A, the conductor structure 1212, and the second end portion 1202B.

Regarding the second BL 1252, the first end portion 1252A and the second end portion 1252B, even physically separated in the same metallization layer M6, may be physically coupled to each other through the third portion 1252C. For example, the first end portion 1252A is connected to one end of the third portion 1252C, and the second end portion 1052B is connected to the other end of the third portion 1252C.

As such, an electrical path 1260 can be formed at least by the first end portion 1252A, the third portion 1252C, and the second end portion 1252B in metallization layer M6. In some embodiments, the electrical path 1260 may be operatively equivalent to the second BL 1252. Alternatively stated, the second BL 1252 can operatively include the first end portion 1252A, the third portion 1252C, and the second end portion 1252B.

In the embodiment of FIG. 12, the conductor structures formed in the metallization layer M6 (e.g., 1202A, 1202B, 1252A, 1252B, 1252C) may extend along the X-direction or Y-direction, and the conductor structures formed between the metallization layers M5 and M6 (e.g., 1212) may be formed as an island spanning along both the X-direction and Y-direction. With one or more “intermediate” portions disposed in the metallization layers and extending in the directions different from the end portions, different BLs, e.g., 1202 (or equivalent path 1220) and 1252 (or equivalent path 1260), can be twisted.

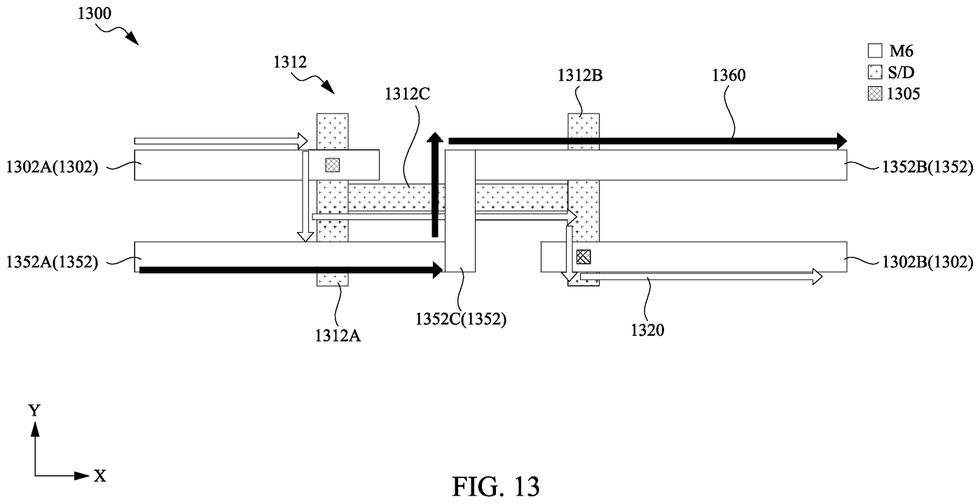

FIG. 13 illustrates an example layout 1300 including a first BL 1302 and a second BL 1352 arranged in a twisted manner, e.g., with one or more their respective portions overlapped with each other (when viewed from the top), in accordance with some embodiments. Each of the first BL 1302 and second BL 1352 may be operatively coupled to a corresponding number of BEOL memory cells (e.g., 200 of FIG. 2).

As shown, the first BL 1302 includes a first end portion 1302A and a second end portion 1302B spaced from each other, and the second BL 1352 includes a first end portion 1352A, a second end portion 1352B, and a third portion 1352C connecting the first end portion 1352A and second end portion 1352B. Each of the first end portions, 1302A and 1352A, and second end portions, 1302B and 1352B, extends along the X-direction, while the third portion 1352C extends along the Y-direction. Further, the first end portion 1302A (of the first BL 1302) is spaced from a projection of the second end portion 1302B (of the first BL 1302) along the Y-direction, and the first end portion 1352A (of the second BL 1352) is spaced from a projection of the second end portion 1352B (of the second BL 1352) along the Y-direction.

Regarding the first BL 1302, the first end portion 1302A and the second end portion 1302B, even physically separated in the same metallization layer M6, may be electrically coupled to each other through a number of conductor structures disposed in one or more metallization layers. For example, the first end portion 1302A is coupled to a conductor structure 1312 (disposed between metallization layers M5 and M6) through one of via structures 1305, and the conductor structure 1312 is coupled to the second end portion 1302B through another one of the via structures 1305. In some embodiments, the conductor structure 1312 may serve as a source or drain terminal (e.g., 216, 218 of FIG. 2) of one or more BEOL memory cells.

As such, an electrical path 1320 can be formed at least by the first end portion 1302A in metallization layer M6, the conductor structure 1312 between metallization layers M5 and M6, and the second end portion 1302B again in metallization layer M6. In some embodiments, the electrical path 1320 may be operatively equivalent to the first BL 1302. Alternatively stated, the first BL 1302 can operatively include the first end portion 1302A, the conductor structure 1312, and the second end portion 1302B.

Regarding the second BL 1352, the first end portion 1352A and the second end portion 1352B, even physically separated in the same metallization layer M6, may be physically coupled to each other through the third portion 1352C. For example, the first end portion 1352A is connected to one end of the third portion 1352C, and the second end portion 1352B is connected to the other end of the third portion 1352C.

As such, an electrical path 1360 can be formed at least by the first end portion 1352A, the third portion 1352C, and the second end portion 1352B in metallization layer M6. In some embodiments, the electrical path 1360 may be operatively equivalent to the second BL 1352. Alternatively stated, the second BL 1352 can operatively include the first end portion 1352A, the third portion 1352C, and the second end portion 1352B.

In the embodiment of FIG. 13, the conductor structures formed in the metallization layer M6 (e.g., 1302A, 1302B, 1352A, 1352B, 1352C) may extend along the X-direction or Y-direction, and the conductor structures formed between the metallization layers M5 and M6 (e.g., 1312) may be formed in an H-shaped profile which consists of a pair of portions extending along the Y-direction (e.g., 1312A and 1312B) and a portion extending along the X-direction and connecting respective middle points of the pair (e.g., 1312C). With one or more “intermediate” portions disposed in the metallization layers and extending in the directions different from the end portions, different BLs, e.g., 1302 (or equivalent path 1320) and 1352 (or equivalent path 1360), can be twisted.

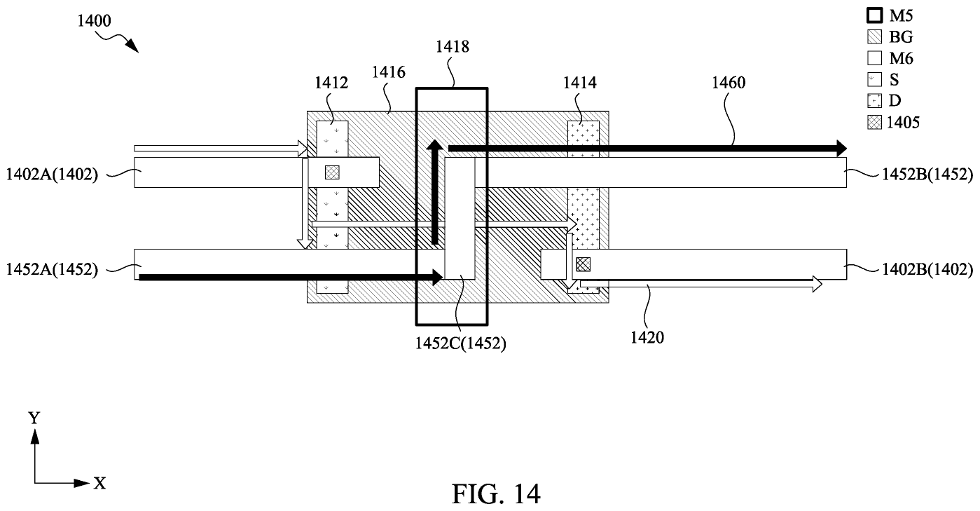

FIG. 14 illustrates an example layout 1400 including a first BL 1402 and a second BL 1452 arranged in a twisted manner, e.g., with one or more their respective portions overlapped with each other (when viewed from the top), in accordance with some embodiments. Each of the first BL 1402 and second BL 1452 may be operatively coupled to a corresponding number of BEOL memory cells (e.g., 200 of FIG. 2).

As shown, the first BL 1402 includes a first end portion 1402A and a second end portion 1402B spaced from each other, and the second BL 1452 includes a first end portion 1452A, a second end portion 1452B, and a third portion 1452C connecting the first end portion 1452A and second end portion 1452B. Each of the first end portions, 1402A and 1452A, and second end portions, 1402B and 1452B, extends along the X-direction, while the third portion 1452C extends along the Y-direction. Further, the first end portion 1402A (of the first BL 1402) is spaced from a projection of the second end portion 1402B (of the first BL 1402) along the Y-direction, and the first end portion 1452A (of the second BL 1452) is spaced from a projection of the second end portion 1452B (of the second BL 1452) along the Y-direction.

Regarding the first BL 1402, the first end portion 1402A and the second end portion 1402B, even physically separated in the same metallization layer M6, may be electrically coupled to each other through a number of conductor structures disposed in one or more metallization layers. For example, the first end portion 1402A is coupled to a conductor structure 1412 (disposed between metallization layers M5 and M6) through one of via structures 1405, and the second end portion 1402B is coupled to another conductor structure 1414 through another one of the via structures 1405. In some embodiments, the conductor structures 1412 and 1414 may serve as a source and a drain terminal (e.g., 216, 218 of FIG. 2) of one BEOL memory cell, respectively. As a reference, BG 1416 and WL 1418 of such a BEOL memory cell are also shown.

As such, an electrical path 1420 can be formed at least by the first end portion 1402A in metallization layer M6, the conductor structure 1412 between metallization layers M5 and M6, a conduction path operatively formed in a channel layer of the corresponding BEOL memory cell that coupled between the conductor structures 1412 and 1414, the conductor structure 1414 between metallization layers M5 and M6, and the second end portion 1402B again in metallization layer M6. In some embodiments, the electrical path 1420 may be operatively equivalent to the first BL 1402. Alternatively stated, the first BL 1402 can operatively include the first end portion 1402A, the conductor structures 1412 and 1414, the channel layer coupling the conductor structure 1412 to the conductor structure 1414, and the second end portion 1402B.

Regarding the second BL 1452, the first end portion 1452A and the second end portion 1452B, even physically separated in the same metallization layer M6, may be physically coupled to each other through the third portion 1452C. For example, the first end portion 1452A is connected to one end of the third portion 1452C, and the second end portion 1452B is connected to the other end of the third portion 1452C.

As such, an electrical path 1460 can be formed at least by the first end portion 1452A, the third portion 1452C, and the second end portion 1452B in metallization layer M6. In some embodiments, the electrical path 1460 may be operatively equivalent to the second BL 1452. Alternatively stated, the second BL 1452 can operatively include the first end portion 1452A, the third portion 1452C, and the second end portion 1452B.

In the embodiment of FIG. 14, the conductor structures formed in the metallization layer M6 (e.g., 1402A, 1402B, 1452A, 1452B, 1452C) may extend along the X-direction or Y-direction, and the conductor structures formed between the metallization layers M5 and M6 (e.g., 1412, 1414) may extend along the Y-direction. With one or more “intermediate” portions disposed in the metallization layers and extending in the directions different from the end portions, different BLs, e.g., 1402 (or equivalent path 1420) and 1452 (or equivalent path 1460), can be twisted.

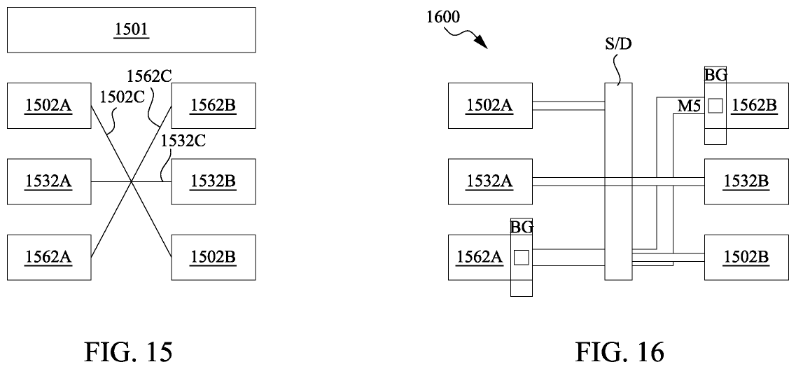

FIG. 15 illustrates a schematic diagram having three twisted BLs, 1502, 1532, and 1562, with a noise source 1501 present nearby, and FIG. 16 illustrates an example layout 1600 corresponding to at least a portion of the schematic diagram of FIG. 15, in accordance with some embodiments.

As shown, each of the BLs 1502 to 1562 includes two end portions, e.g., the BL 1502 including 1502A and 1502B, the BL 1532 including 1532A and 1532B, and the BL 1562 including 1562A and 1562B. By placing each BL's respective end portions with respect to the noise source 1501 by different distances, the coupling of noise can be balanced out, which can advantageously mitigate the impact of noise on the BLs. With the end portions of each BL arranged in this way, each of the BLs may have one or more intermediate portions twisted with at least another BL. For example, the end portions 1502A and 1502B of the BL 1502 may be coupled to each other through intermediate portion 1502C, the end portions 1532A and 1532B of the BL 1532 may be coupled to each other through intermediate portion 1532C, and the end portions 1562A and 1562B of the BL 1562 may be coupled to each other through intermediate portion 1562C. In the illustrated example of FIG. 15, the intermediate portions 1502C, 1532C, and 1562C may be twisted or otherwise overlapped with one another.

The layout 1600 of FIG. 16 is an example implementation of the example shown in FIG. 15. As illustrated, the end portions 1502A and 1502B (disposed in metallization layer M6) may be coupled to each other through a conductor structure disposed below the end portions 1502A-B and configured as the source/drain terminal of one BEOL memory cell, just like the example layouts 700, 800, 900, 1000, and 1100 shown in FIGS. 7, 8, 9, 10, and 11, respectively. Such a conductor structure may be an implementation of the intermediate portion 1502C. The end portions 1532A and 1532B (disposed in metallization layer M6) may be coupled to each other through a conductor structure disposed in the same metallization layer as them. Such a conductor structure may be an implementation of the intermediate portion 1532C. The end portions 1562A and 1562B (disposed in metallization layer M6) may be coupled to each other through a conductor structure (disposed in metallization layer M5), just like the example layouts 600 and 700 shown in FIGS. 6 and 7, respectively. Such a conductor structure may be an implementation of the intermediate portion 1562C.

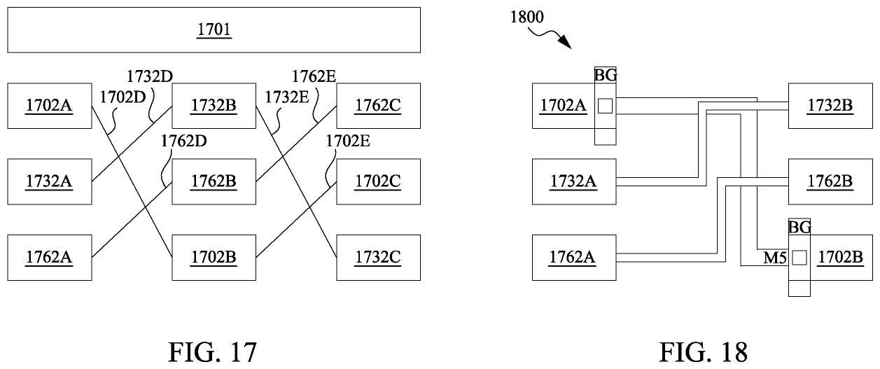

FIG. 17 illustrates a schematic diagram having three twisted BLs, 1702, 1732, and 1762, with a noise source 1701 present nearby, and FIG. 18 illustrates an example layout 1800 corresponding to at least a portion of the schematic diagram of FIG. 17, in accordance with some embodiments.

As shown, each of the BLs 1702 to 1762 includes three end portions, e.g., the BL 1702 including 1702A, 1702B, and 1702C, the BL 1732 including 1732A, 1732B, and 1732C, and the BL 1762 including 1762A, 1762B, and 1762C. By placing each BL's respective end portions with respect to the noise source 1701 by different distances, the coupling of noise can be balanced out, which can advantageously mitigate the impact of noise on the BLs. With the end portions of each BL arranged in this way, each of the BLs may have one or more intermediate portions twisted with at least another BL. For example, the end portions 1702A and 1702B of the BL 1702 may be coupled to each other through intermediate portion 1702D, the end portions 1702B and 1702C of the BL 1702 may be coupled to each other through intermediate portion 1702E, the end portions 1732A and 1732B of the BL 1732 may be coupled to each other through intermediate portion 1732D, the end portions 1732B and 1732C of the BL 1732 may be coupled to each other through intermediate portion 1732E, the end portions 1762A and 1762B of the BL 1762 may be coupled to each other through intermediate portion 1762D, and the end portions 1762B and 1762C of the BL 1762 may be coupled to each other through intermediate portion 1762E. In the illustrated example of FIG. 17, the intermediate portions 1702D, 1702E, 1732D, 1732E, 1762D, and 1762E may be twisted or otherwise overlapped with one another.

The layout 1800 of FIG. 18 is an example implementation of a portion of the example shown in FIG. 17. As illustrated, the end portions 1702A and 1702B (disposed in metallization layer M6) may be coupled to each other through a conductor structure (disposed in metallization layer M5), just like the example layouts 600 and 700 shown in FIGS. 6 and 7, respectively. Such a conductor structure may be an implementation of the intermediate portion 1702D. The end portions 1732A and 1732B (disposed in metallization layer M6) may be coupled to each other through a conductor structure disposed in the same metallization layer as them. Such a conductor structure may be an implementation of the intermediate portion 1732D. The end portions 1762A and 1762B (disposed in metallization layer M6) may be coupled to each other through a conductor structure disposed in the same metallization layer as them. Such a conductor structure may be an implementation of the intermediate portion 1762D.

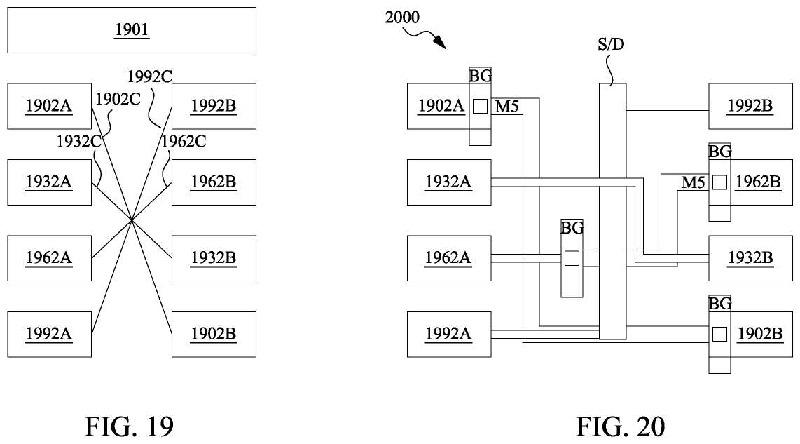

FIG. 19 illustrates a schematic diagram having four twisted BLs, 1902, 1932, 1962, and 1992, with a noise source 1901 present nearby, and FIG. 20 illustrates an example layout 2000 corresponding to at least a portion of the schematic diagram of FIG. 19, in accordance with some embodiments.

As shown, each of the BLs 1902 to 1992 includes two end portions, e.g., the BL 1902 including 1902A and 1902B, the BL 1932 including 1932A and 1932B, the BL 1962 including 1962A and 1962B, and the BL 1992 including 1992A and 1992B. By placing each BL's respective end portions with respect to the noise source 1901 by different distances, the coupling of noise can be balanced out, which can advantageously mitigate the impact of noise on the BLs. With the end portions of each BL arranged in this way, each of the BLs may have one or more intermediate portions twisted with at least another BL. For example, the end portions 1902A and 1902B of the BL 1902 may be coupled to each other through intermediate portion 1902C, the end portions 1932A and 1932B of the BL 1932 may be coupled to each other through intermediate portion 1932C, the end portions 1962A and 1962B of the BL 1962 may be coupled to each other through intermediate portion 1962C, and the end portions 1992A and 1992B of the BL 1992 may be coupled to each other through intermediate portion 1992C. In the illustrated example of FIG. 19, the intermediate portions 1902C, 1932C,1962C, and 1992C may be twisted or otherwise overlapped with one another.

The layout 2000 of FIG. 20 is an example implementation of the example shown in FIG. 19. As illustrated, the end portions 1902A and 1902B (disposed in metallization layer M6) may be coupled to each other through a conductor structure (disposed in metallization layer M5), just like the example layouts 600 and 700 shown in FIGS. 6 and 7, respectively. Such a conductor structure may be an implementation of the intermediate portion 1902C. The end portions 1932A and 1932B (disposed in metallization layer M6) may be coupled to each other through a conductor structure disposed in the same metallization layer as them. Such a conductor structure may be an implementation of the intermediate portion 1932C. The end portions 1962A and 1962B (disposed in metallization layer M6) may be coupled to each other through a conductor structure (disposed in metallization layer M5), just like the example layouts 600 and 700 shown in FIGS. 6 and 7, respectively. Such a conductor structure may be an implementation of the intermediate portion 1962C. The end portions 1992A and 1992B (disposed in metallization layer M6) may be coupled to each other through a conductor structure disposed below the end portions 1902A-B and configured as the source/drain terminal of one BEOL memory cell, just like the example layouts 700, 800, 900, 1000, and 1100 shown in FIGS. 7, 8, 9, 10, and 11, respectively. Such a conductor structure may be an implementation of the intermediate portion 1992C.

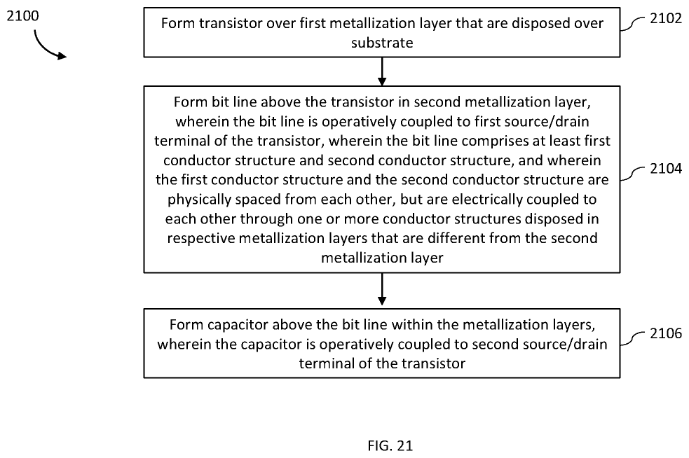

FIG. 21 illustrates a flow chart of an example method 2100 for fabricating a memory device that is coupled to a corresponding one of twisted BLs (as shown in the example layouts 600-1400 of FIGS. 6-14, respectively), according to various aspects of the present disclosure. For example, some operations of the method 2100 can be used to fabricate a number of BLs, each of which is operatively coupled to a corresponding number of BEOL memory cells and has at least one intermediate portion overlapped with the intermediate portion of another BL.

It should be noted that the method 2100 is merely an example, and is not intended to limit the present disclosure. Accordingly, it should be understood that additional operations may be provided before, during, and/or after the method 2100, and that some other operations may only be briefly described herein. The following discussions of the method 2100 may refer to one or more components discussed with respect to FIGS. 1-20.

The method 2100 start with operation 2102 in which a transistor is formed over at least a first one of a number of metallization layers over a semiconductor substrate, in accordance with some embodiments.

The semiconductor substrate may be a semiconductor substrate, such as a bulk semiconductor, a semiconductor-on-insulator (SOI) substrate, or the like, which may be doped (e.g., with a p-type or an n-type dopant) or undoped. The substrate may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

The metallization layers each include a number of conductor structures embedded in a corresponding IMD/ILD. The conductor structures can include a number of back-end-of-line (BEOL) conductor lines or islands such as, for example, conductor structure 210, 216, 218, WL 222, BL 224, etc. Each of the conductor structures can include one or more metal materials such as, for example, tungsten (W), copper (Cu), gold (Au), cobalt (Co), ruthenium (Ru), or combinations thereof. The IMD/ILD, embedding the interconnect structure, can include one or more of a low-k dielectric layer (i.e., a dielectric with a dielectric constant less than about 3.9), an ultra low-k dielectric layer, or an oxide (e.g., silicon oxide).

The transistor formed within one or between adjacent ones of the metallization layers may sometimes be referred to as a BEOL transistor. Such a BEOL transistor can be implemented as two-dimensional back-gate transistor (e.g., 202), which can have its channel formed of one or more semiconductive-behaving oxide materials such as, for example, IGZO, InZnO, InSnO, SnO₂, MgAlZnO, etc., or one or more 2D materials such as, for example, transition metal dichalcogenide (TMD) material, graphene, etc. In the examples discussed above, the BEOL transistor may be formed over metallization layers M0 to M4 and between metallization layers M5 and M6 (FIG. 5).

The method 2100 continues to operation 2104 in which a bit line is formed in a second one of the plurality of metallization layers, in accordance with some embodiments.

The bit line is operatively coupled to a first source/drain terminal of the BEOL transistor formed in operation 2102. In various embodiments, the bit line may include at least a first conductor structure and a second conductor structure physically spaced from each other, but are electrically coupled to each other through one or more conductor structures disposed in respective ones of the metallization layers that are different from the second metallization layer.

As a non-limiting example, in FIG. 6, the bit line (e.g., 602) may include a first conductor structure 602A and a second conductor structure 602B disposed in metallization layer M6, where the first conductor structure 602A and second conductor structure 602B are coupled to each other through conductor structures 612, 614, and 616. These conductor structures connecting the first conductor structure 602A and the second conductor structure 602B are disposed across metallization layers M4 to M5. Similarly, in FIG. 6, another bit line (e.g., 652) can be formed a first conductor structure 652A and a second conductor structure 652B disposed in metallization layer M6, which are coupled to each other through conductor structures 622, 624, and 626 formed across metallization layers M4 to M5. As such, the bit lines 602 and 652 are twisted with each other, according to various embodiments of the present disclosure. As another non-limiting example, in FIG. 7, the bit line (e.g., 752) may include first conductor structure 752A and second conductor structure 752B disposed in metallization layer M6, where the first conductor structure 752A and second conductor structure 752B are coupled to each other through conductor structure 722 (the source/drain terminal of one BEOL memory cell) that is disposed between metallization layers M5 and M6. As yet another non-limiting example, in FIG. 9, the bit line (e.g., 902) may include first conductor structure 902A and second conductor structure 90B disposed in metallization layer M6, where the first conductor structure 902A and second conductor structure 902B are coupled to each other through conductor structure 912 (formed in an L-shaped profile) that is disposed in metallization layer M5.

The method 2100 continues to operation 2106 in which a capacitor is formed within the plurality of metallization layers and above the bit line, in accordance with some embodiments.

The capacitor is operatively coupled to a second source/drain terminal of the BEOL transistor formed in operation 2102. In various embodiments, the capacitor may be formed as an MIM or MOM structure (e.g., 204) that includes a bottom electrode and a top electrode sandwiching a capacitor dielectric layer. In the above example where the bit line is formed in metallization layer M6, the capacitor can be formed between metallization layers M6 and M7.

In one aspect of the present disclosure, a memory device is disclosed. The memory device includes a substrate; a plurality of metallization layers disposed over the substrate; a plurality of memory cells, each of the plurality of memory cells including a transistor and a capacitor; and a bit line coupled to a corresponding set of the plurality of memory cells. The bit line comprises at least a first conductor structure and a second conductor structure that extend along a first lateral direction and are disposed in a first one of the plurality of metallization layers. The first conductor structure and the second conductor structure are physically spaced from each other, but are electrically coupled to each other through conductor structures disposed in one or more of the plurality of metallization layers.

In another aspect of the present disclosure, a memory device is disclosed. The memory device includes a plurality of memory cells disposed across one or more of a plurality of metallization layers formed over a substrate; and a bit line operatively coupled to a corresponding set of the plurality of memory cells. The bit line consists of at least a first conductor structure and a second conductor structure that are disposed in a first one of the plurality of metallization layers. The first conductor structure and the second conductor structure are physically spaced from each other, but are electrically coupled to each other through one or more other conductor structures.

In yet another aspect of the present disclosure, a method for fabricating memory devices is disclosed. The method includes forming a transistor over at least a first one of a plurality of metallization layers that are disposed over a substrate. The method includes forming a bit line above the transistor in a second one of the plurality of metallization layers, wherein the bit line is operatively coupled to a first source/drain terminal of the transistor. The method includes forming a capacitor above the bit line within the plurality of metallization layers, wherein the capacitor is operatively coupled to a second source/drain terminal of the transistor. The bit line comprises at least a first conductor structure and a second conductor structure, and wherein the first conductor structure and the second conductor structure are physically spaced from each other, but are electrically coupled to each other through one or more conductor structures disposed in respective ones of the metallization layers that are different from the second metallization layer.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a substrate;
a plurality of metallization layers disposed over the substrate;
a plurality of memory cells, each of the plurality of memory cells including a transistor and a capacitor; and
a bit line coupled to a corresponding set of the plurality of memory cells;
wherein the bit line comprises at least a first conductor structure and a second conductor structure that extend along a first lateral direction and are disposed in a first one of the plurality of metallization layers;
wherein the first conductor structure and the second conductor structure are physically spaced from each other, but are electrically coupled to each other through conductor structures disposed in one or more of the plurality of metallization layers.

2. The memory device of claim 1, wherein the transistor and the capacitor of each of the memory cell are formed across multiple ones of the plurality of metallization layers.

3. The memory device of claim 1, wherein the first conductor structure and a projection of the second conductor structure are physically spaced from each other along a second lateral direction perpendicular to the first lateral direction.

4. The memory device of claim 3, wherein the conductor structures comprise:
a third conductor structure disposed in a second one of the plurality of metallization layers and extending along the second lateral direction;
a fourth conductive line disposed in a third one of the plurality of metallization layers and extending along the first lateral direction; and
a fifth conductor structure disposed in the second metallization layer and extending along the second lateral direction.

5. The memory device of claim 3, wherein the conductor structures comprise a source/drain structure of one of the corresponding set of memory cells, and wherein the source/drain structure extends along the second lateral direction.

6. The memory device of claim 3, wherein the conductor structures comprise an island structure disposed in a second one of the plurality of metallization layers.

7. The memory device of claim 3, wherein the conductor structures comprise a third conductor structure disposed in a second one of the plurality of metallization layers, and having a first portion and a second portion that extend along the first lateral direction and the second lateral direction, respectively.

8. The memory device of claim 3, wherein the conductor structures comprise a gate structure of one or more of the corresponding set of memory cells, and wherein the gate structure is formed as an island structure.

9. The memory device of claim 3, wherein the conductor structures comprise a gate structure of one or more of the corresponding set of memory cells, and wherein the gate structure is formed as having a first portion and a second portion that extend along the first lateral direction and the second lateral direction, respectively.

10. The memory device of claim 1, wherein the conductor structures comprise a source/drain structure of one of the corresponding set of memory cells, and wherein the source/drain structure is formed as an island structure.

11. The memory device of claim 1, wherein the conductor structures comprise a source/drain structure of one of the corresponding set of memory cells, and wherein the source/drain structure is formed as an H-shaped structure.

12. A memory device, comprising:
a plurality of memory cells disposed across one or more of a plurality of metallization layers formed over a substrate; and
a bit line operatively coupled to a corresponding set of the plurality of memory cells;
wherein the bit line consists of at least a first conductor structure and a second conductor structure that are disposed in a first one of the plurality of metallization layers;
wherein the first conductor structure and the second conductor structure are physically spaced from each other, but are electrically coupled to each other through one or more other conductor structures.

13. The memory device of claim 12, wherein the first conductor structure and the second conductor structure both extend along a first lateral direction, and wherein the first conductor structure and a projection of the second conductor structure are physically spaced from each other along a second lateral direction perpendicular to the first lateral direction.

14. The memory device of claim 13, wherein the one or more other conductor structures comprise:
a third conductor structure disposed in a second one of the plurality of metallization layers and extending along the second lateral direction;
a fourth conductive line disposed in a third one of the plurality of metallization layers and extending along the first lateral direction; and
a fifth conductor structure disposed in the second metallization layer and extending along the second lateral direction.

15. The memory device of claim 13, wherein the one or more other conductor structures comprise a source/drain structure of one of the memory cells.

16. The memory device of claim 13, wherein the one or more other conductor structures comprise an island structure disposed in a second one of the plurality of metallization layers.

17. The memory device of claim 13, wherein the one or more other conductor structures comprise a third conductor structure disposed in a second one of the plurality of metallization layers, and having a first portion and a second portion that extend along the first lateral direction and the second lateral direction, respectively.

18. The memory device of claim 13, wherein the one or more other conductor structures comprise a gate structure of one or more of the memory cells.

19. A method for forming memory devices, comprising:
forming a transistor over at least a first one of a plurality of metallization layers that are disposed over a substrate;
forming a bit line above the transistor in a second one of the plurality of metallization layers, wherein the bit line is operatively coupled to a first source/drain terminal of the transistor; and
forming a capacitor above the bit line within the plurality of metallization layers, wherein the capacitor is operatively coupled to a second source/drain terminal of the transistor;
wherein the bit line comprises at least a first conductor structure and a second conductor structure, and wherein the first conductor structure and the second conductor structure are physically spaced from each other, but are electrically coupled to each other through one or more conductor structures disposed in respective ones of the metallization layers that are different from the second metallization layer.

20. The method of claim 19, wherein the first conductor structure and the second conductor structure both extend along a first lateral direction, and wherein the first conductor structure and a projection of the second conductor structure are physically spaced from each other along a second lateral direction perpendicular to the first lateral direction.
